(19) United States
(12) Patent Application Publication
(10) Pub. No.: US 2018/0277647 A1
(43) Pub. Date: Sep. 27, 2018

(54) NONVOLATILE MEMORY DEVICE

(71) Applicant: SK hynix Inc., Icheon (KR)

(72) Inventor: Hyangkeun YOO, Icheon-si (KR)

(21) Appl. No.: 15/826,616

(22) Filed: Nov. 29, 2017

(30) Foreign Application Priority Data
Mar. 21, 2017 (KR) 10-2017-0035341

(51) Int. Cl. H01L 29/51; H01L 29/423

(52) U.S. Cl. CPC H01L 29/513; H01L 29/4234; H01L 29/792; H01L 29/517; H01L 29/518; H01L 29/42364

(57) ABSTRACT

A nonvolatile memory device includes a semiconductor substrate, a tunnel insulation layer disposed on the semiconductor substrate, a charge trap layer disposed on the tunnel insulation layer, and a control gate electrode disposed on the charge trap layer. The tunnel insulation layer includes an antiferroelectric material.

### CROSS-REFERENCE TO RELATED APPLICATION

The present application claims priority under 35 U.S.C. 119(a) to Korean Patent Application No. 10-2017-0035341, filed on Mar. 21, 2017, which is herein incorporated by reference in its entirety.

### BACKGROUND

### 1. Technical Field

Embodiments of the present disclosure relate to a nonvolatile memory device.

### 2. Related Art

Generally, a nonvolatile memory device refers to a memory device in which inputted information does not disappear when power is not supplied externally. A flash memory device is a typical nonvolatile memory device.

A flash memory device may include a charge storage layer and a control electrode disposed on a semiconductor substrate. The flash memory device can store electrical information by controlling the amount of charges charged or stored from the semiconductor substrate to the charge storage layer using the control electrode.

Generally, a flash memory device can be classified into a floating gate type device and a charge trap type device depending on the structure of the charge storage layer. The charge trap type device may include a tunnel insulation layer, a charge storage layer, a blocking insulation layer, and a control gate electrode that are sequentially disposed on a semiconductor substrate. The charge trap type device can trap or de-trap charges using trap sites located in the charge storage layer. In addition, the charge trap type device can supply charges to the charge storage layer using a tunneling phenomenon occurring between the semiconductor substrate and the charge storage layer. Depending on the amount of the charges trapped in the charge storage layer, a single level or a multilevel electrical signal can be implemented.

### SUMMARY

An aspect of the present disclosure provides a nonvolatile memory device that can increase a charge filling efficiency or a charge removal efficiency of a charge trap layer.

A nonvolatile memory device according to an aspect of the present disclosure includes a semiconductor substrate, a tunnel insulation layer disposed on the semiconductor substrate, a charge trap layer disposed on the tunnel insulation layer, and a control gate electrode disposed on the charge trap layer. The tunnel insulation layer includes an antiferroelectric material.

A nonvolatile memory device according to another aspect of the present disclosure includes a semiconductor substrate, a tunnel insulation layer disposed on the semiconductor substrate, a charge trap layer disposed on the tunnel insulation layer, and a control gate electrode disposed on the charge trap layer. The tunnel insulation layer has a nonlinearly increasing polarization value which improves tunneling of charges between the semiconductor substrate and the charge trap layer when an electric field of an absolute magnitude greater than or equal to an absolute magnitude of a threshold voltage is formed in the tunnel insulation layer. When the voltage applied to the control gate electrode is removed, the polarization state of the tunnel insulation layer decreases or disappears.

A nonvolatile memory device according to yet another aspect of the present disclosure includes a semiconductor substrate, an interfacial insulation layer disposed on the semiconductor substrate, an antiferroelectric tunnel insulation layer disposed on the interfacial insulation layer, a charge trap nitride layer disposed on the tunnel insulation layer, and a control gate electrode disposed on the charge trap nitride layer. The tunnel insulation layer includes one selected from a zirconium oxide, a hafnium oxide, and a zirconium hafnium oxide. The interfacial insulation layer includes one selected from a silicon oxide, a silicon oxynitride, and a silicon nitride.

### BRIEF DESCRIPTION OF THE DRAWINGS

FIG. 1 is cross-sectional view schematically illustrating a nonvolatile memory device according to an embodiment of the present disclosure.

FIG. 2 is a hysteresis graph showing antiferroelectricity characteristics of a tunnel insulation layer of a nonvolatile memory device according to an embodiment of the present disclosure.

FIGS. 3 and 4 are views schematically illustrating operations of a nonvolatile memory device according to embodiments of the present disclosure.

FIG. 5A is an energy diagram schematically illustrating a programming operation of a nonvolatile memory device according to an embodiment of the present disclosure.

FIG. 5B is an enlarged view schematically illustrating an interface between a tunnel insulation layer and a charge trap layer of the nonvolatile memory device of FIG. 5A.

FIG. 6A is an energy diagram schematically illustrating an erase operation of a nonvolatile memory device according to an embodiment of the present disclosure.

FIG. 6B is an enlarged view schematically illustrating an interface between a tunnel insulation layer and a charge trap layer of the nonvolatile memory device of FIG. 6A.

FIG. 7A is an energy diagram schematically illustrating a state in which a programming operation of a nonvolatile memory device according to an embodiment of the present disclosure is completed.

FIG. 7B is an enlarged view schematically illustrating an interface between a tunnel insulation layer and a charge trap layer of the nonvolatile memory device of FIG. 7A.

### DETAILED DESCRIPTION

Various embodiments will now be described hereinafter with reference to the accompanying drawings. In the drawings, the dimensions of layers and regions may be exaggerated for clarity of illustration. The drawings are described with respect to an observer's viewpoint. If a first element is referred to as located on a second element, it may be understood that the first element is directly located on the second element; that an additional element may be interposed between the first element and the second element; or that a portion of the first element is directly located on a portion of the second element. The same reference numerals may refer to the same elements throughout the specification.

In addition, expression of a singular form of a word includes the plural forms of the word unless clearly used otherwise in the context of the disclosure. The terms “comprise”, “have” or “include” are intended to specify the presence of a feature, a number, a step, an operation, an element, a component, a part, or combinations thereof, but the terms do not preclude the presence or possibility of the addition of one or more other features, numbers, steps, operations, elements, components, parts, or combinations thereof.

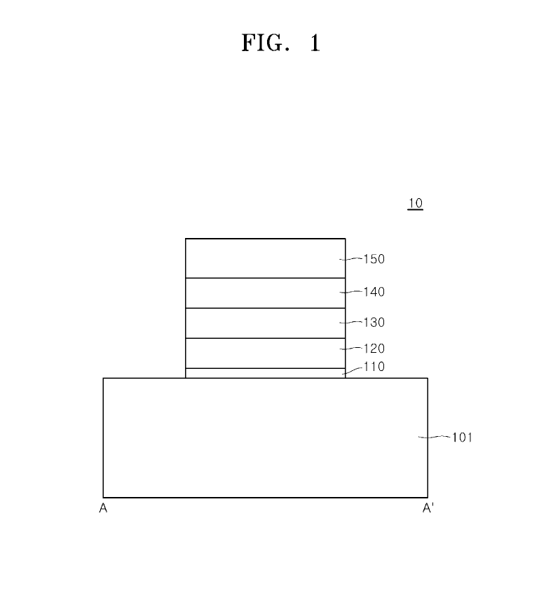

FIG. 1 is a cross-sectional view schematically illustrating a nonvolatile memory device 10 according to an embodiment of the present disclosure. Referring to FIG. 1, nonvolatile memory device 10 may include a semiconductor substrate 101, a tunnel insulation layer 120, a charge trap layer 130, and a control gate electrode 150. The nonvolatile memory device 10 may further include an interfacial insulation layer 110 disposed between the semiconductor substrate 101 and the tunnel insulation layer 120. The nonvolatile memory device 10 may further include a charge blocking layer 140 disposed between the charge trap layer 130 and the control gate electrode 150.

The semiconductor substrate 101 may be a silicon (Si) substrate, a gallium arsenide (GaAs) substrate, an indium phosphide (InP) substrate, a germanium (Ge) substrate, or a silicon germanium (SiGe) substrate, as non-limiting examples. The semiconductor substrate 101 may be doped, for example, with n-type or p-type impurities to have conductivity.

Although it is not illustrated, a source region and a drain region may be formed in the semiconductor substrate 101. Each of the source region and drain region may be an n-type doped or a p-type doped region in the semiconductor substrate 101. As an example, the source region and drain region may be doped with a doping type opposite to that of the semiconductor substrate 101.

The interfacial insulation layer 110 may be disposed between the semiconductor substrate 101 and the tunnel insulation layer 120. The interfacial insulation layer 110 can suppress the generation of trap sites at an interface of heterogeneous material layers when the semiconductor substrate 101 and the tunnel insulation layer 120 directly form an interface. In other words, the interfacial insulation layer 110 can reduce the density of the trap sites acting as a path of a leakage current between the semiconductor substrate 101 and the tunnel insulation layer 120.

The interfacial insulation layer 110 may, for example, include silicon oxide, silicon nitride, or silicon oxynitride, as non-limiting examples. In some cases, the interfacial insulation layer 110 may have an amorphous structure. In some embodiments, the interfacial insulation layer 110 may have a thickness of about five nanometers (5 nm) or less. As another example, the interfacial insulation layer 110 may have a thickness of one or two nm.

The tunnel insulation layer 120 may be disposed on the interfacial insulation layer 110. In an embodiment, electrons or holes may tunnel through tunnel insulation layer 120 from the semiconductor substrate 101 to the charge trap layer 130 when a voltage is applied to control gate electrode 150.

In an embodiment, the tunnel insulation layer 120 may include an antiferroelectric material. The antiferroelectric material may include zirconium oxide, hafnium oxide, or zirconium hafnium oxide, as non-limiting examples. In an example, the antiferroelectric material may include aluminum (Al) or silicon (Si) as a dopant. In another example, the zirconium hafnium oxide may be hafnium-doped zirconium oxide. In yet another example, the zirconium hafnium oxide may be a solid solution in which the content of zirconium and hafnium therein can be changed.

In an embodiment, the tunnel insulation layer 120 may include a zirconium oxide layer having a thickness of about one (1) nm to thirty five (35) nm. In another embodiment, the tunnel insulation layer 120 may have a thickness of about one (1) nm to twenty (20) nm and may include an aluminum-doped hafnium oxide layer or a silicon-doped hafnium oxide layer. The tunnel insulation layer 120 may be formed using an atomic layer deposition method, a molecular beam deposition method, an evaporation method, a chemical vapor deposition method, or the like, as non-limiting examples.

It has been reported in recent research that a high-dielectric material such as the above-described zirconium oxide, hafnium oxide, or zirconium hafnium oxide has an antiferroelectric characteristic when it is manufactured in the form of a thin film, and not in a bulk form. As an example, J. Müller, et al. (Nano Lett., 2012, 12 (8), pp 4318-4323) have disclosed a hysteresis curve that illustrates antiferroelectricity in a zirconium oxide thin film.

In a nonvolatile memory device 10 according to an embodiment, the tunneling efficiency of electrons or holes between the semiconductor substrate 101 and the charge trap layer 130 can be increased by polarizing the tunneling insulation layer 120 having antiferroelectricity to a predetermined polarization state.

The charge trap layer 130 may be disposed on the tunnel insulation layer 120. The charge trap layer 130 may have trap sites to store charges flowing into the charge trap layer 130. The charge trap layer 130 may, for example, include silicon nitride, silicon oxynitride, or metal oxide, as non-limiting examples. A trap site in the charge trap layer 130 may, as an example, be formed by doping with dopants or, in another example, be formed by a wet oxidation process.

The band gap energy of the charge trap layer 130 may be smaller than the band gap energy of the tunnel insulation layer 120 and the band gap energy of the charge blocking layer 140. Accordingly, charges trapped in the charge trap layer 130 can be prevented, suppressed, or impeded from deviating to the semiconductor substrate 101 and the control gate electrode 150 by an energy barrier formed between the charge trap layer 130 and the tunnel insulation layer 120, and by an energy barrier formed between the charge trap layer 130 and the charge blocking layer 140.

In an embodiment, in a nonvolatile memory device 10, a single level signal or a multilevel signal can be distinguished from each other according to the amount of charges stored in the charge trap layer 130.

The charge blocking layer 140 may be disposed on the charge trap layer 130 to form an interface with the charge trap layer 130. The charge blocking layer 140 can form an energy barrier between the charge trap layer 130 and the control gate electrode 150 so that charges trapped in the charge trap layer 130 do not deviate toward or pass into the control gate electrode 150. The charge blocking layer 140 may include, for example, silicon oxide, silicon oxynitride, aluminum oxide, hafnium oxide, hafnium aluminum oxide, hafnium silicon oxide, or the like, as non-limiting examples.

The control gate electrode 150 may be disposed on the charge blocking layer 140. The control gate electrode 150 may control the movement of electrons or holes between the substrate 101 and the charge trap layer 130. The control gate electrode 150 may include a conductive material. The control gate electrode 150 may include, for example, doped silicon, tungsten, titanium nitride, tantalum nitride, tungsten nitride, tungsten silicide, or the like, as non-limiting examples.

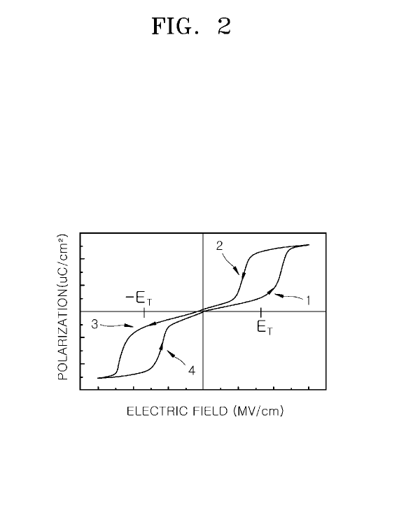

FIG. 2 is a hysteresis graph illustrating antiferroelectricity characteristics of a tunnel insulation layer of a nonvolatile memory device according to an embodiment of the present disclosure. The tunnel insulation layer may include an antiferroelectric material.

Referring to FIG. 2, in an embodiment, when a positive bias is applied to one end of, or an interface common to, the tunnel insulation layer, and the positive bias increases to a threshold electric field E_{T} or more, the tunnel insulation layer may have a high polarization value that nonlinearly increases along graph 1. Subsequently, as the applied positive bias is reduced, the polarization value of the tunnel insulation layer can also be reduced along graph 2. Further, when the bias applied to the tunnel insulation layer is removed, a polarization state due to the bias can be substantially eliminated.

In addition, referring to FIG. 2, when a negative bias is applied to one end of, or an interface common to, the tunnel insulation layer 120, and the negative bias is increased to a threshold electric field −E_{T} or more, the tunnel insulation layer may have a high polarization value (in absolute value) that nonlinearly increases along graph 3. Subsequently, as the applied negative bias is reduced, the polarization value (in absolute value) of the tunnel insulation layer can be reduced along graph 4. Further, when the negative bias applied to the tunnel insulation layer is removed, a polarization state due to the bias can be substantially eliminated.

In this embodiment of the present disclosure, a strong polarization state in a tunnel insulation layer 120 having an antiferroelectric material can be used to increase the tunneling efficiency of charges passing through the tunnel insulation layer, when an absolute magnitude of an electric field is greater than or equal to an absolute magnitude of the threshold electric field E_{T}, −E_{T}.

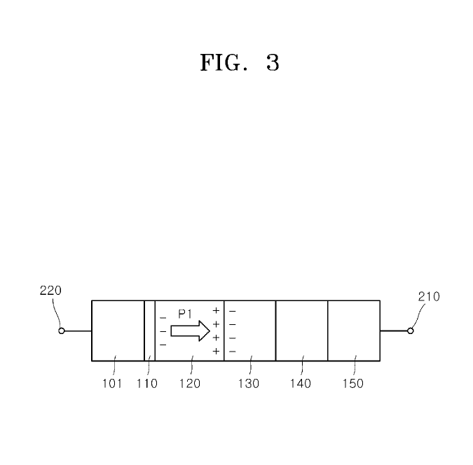

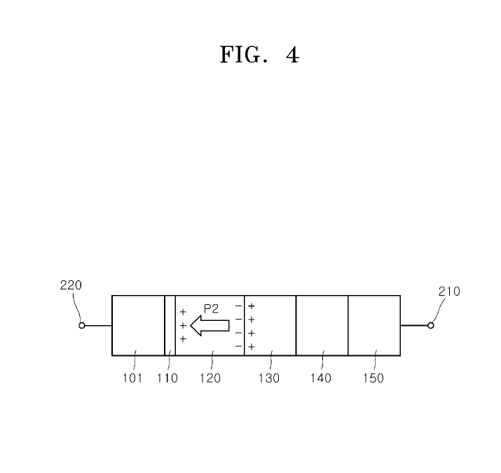

FIGS. 3 and 4 are views schematically illustrating operations of a nonvolatile memory device according to embodiments of the present disclosure. Specifically, FIG. 3 schematically illustrates a programming operation of a nonvolatile memory device, and FIG. 4 schematically illustrates an erase operation of a nonvolatile memory device. A configuration of the nonvolatile memory device may be substantially the same as a configuration of the nonvolatile memory device described above and with reference to FIGS. 1 and 2. In other words, a tunnel insulation layer of a nonvolatile memory device may include an antiferroelectric material.

Referring to FIG. 3, in an embodiment, a programming operation may be performed by applying a positive bias to a control gate electrode 150 through a first terminal 210, and applying a relatively negative bias to a semiconductor substrate 101 through a second terminal 220. In a programming operation, electrons may tunnel from a semiconductor substrate 101 to a charge trap layer 130 by moving from the negative bias towards the positive bias. The tunnel insulation layer 120 can be electrically polarized at least in part by the electrons trapped in the charge trap layer 130. In an embodiment, one region of the tunnel insulation layer 120, which interfaces with the interfacial insulation layer 110, can be charged with negative charges and another region of the tunnel insulation layer 120, which interfaces with the charge trap layer 130, can be charged with positive charges. At this time, if an electric field of a magnitude greater than or equal to a magnitude of the threshold electric field E_{T}, described above and with reference to FIG. 2, is formed at both ends of the tunnel insulation layer 120, near the interfaces with interfacial insulation layer 110 and charge trap layer 130 respectively, then the tunnel insulation layer 120 can have a high polarization P1 that increases nonlinearly. The polarization P1 can increase the tunneling efficiency of electrons from the semiconductor substrate 101 toward the charge trap layer 130 by acting as an attractive force on the electrons in the semiconductor substrate 101.

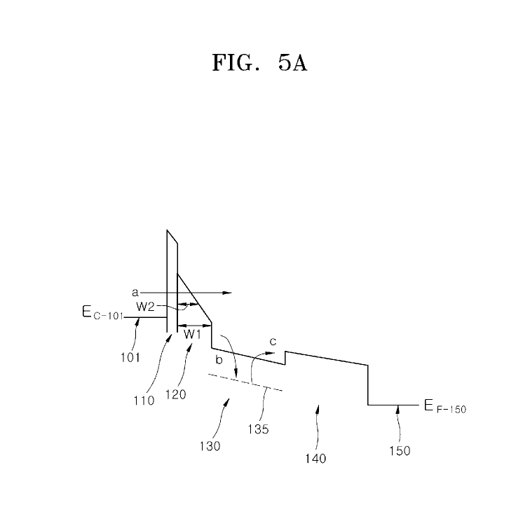

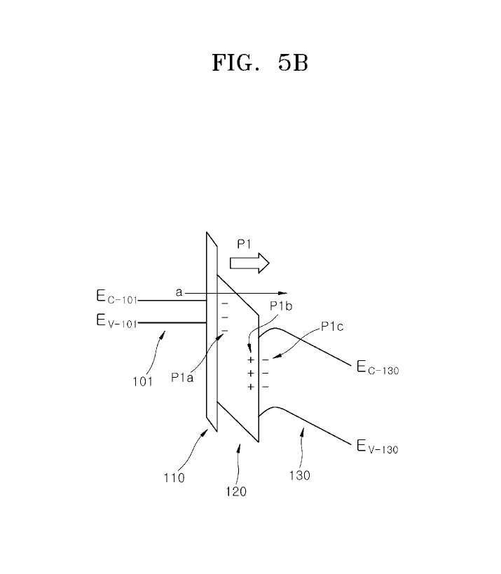

In addition, the polarization P1 of the tunnel insulation layer 120 can, for example, help to reduce a tunneling barrier width of the electrons during the programming operation, as illustrated in energy band diagrams of FIGS. 5A and 5B described later. As a result, the polarization P1 of the tunnel insulation layer 120 can increase the Fowler-Nordheim (FN) tunneling efficiency of electrons.

As a result, the reliability of a programming operation of a nonvolatile memory device can be improved by utilizing the antiferroelectricity of the tunnel insulation layer 120. Further, the magnitude of the voltage required for a programming operation can be reduced by utilizing the antiferroelectricity of the tunnel insulation layer 120. Thus, the power consumption of the nonvolatile memory device can be reduced.

Referring to FIG. 4, in an embodiment, an erase operation of a nonvolatile memory device may be performed by applying a negative bias to a control gate electrode 150 through first terminal 210, and applying a relatively positive bias to semiconductor substrate 101 through second terminal 220. In an erase operation, holes can tunnel from the semiconductor substrate 101 to the charge trap layer 130 by moving from the positive bias towards the negative bias. The tunnel insulation layer 120 can be electrically polarized at least in part by the holes trapped in the charge trap layer 130. In an embodiment, one region of the tunnel insulation layer 120, which interfaces with the interfacial insulation layer 110, can be charged with positive charges and another region of the tunnel insulation layer 120, which interfaces with the charge trap layer 130, can be charged with negative charges. At this time, if an electric field having an absolute magnitude greater than or equal to an absolute magnitude of the threshold electric field −E_{T} described above with reference to FIG. 2 is formed at both ends of the tunnel insulation layer 120, near the interfaces with interfacial insulation layer 110 and charge trap layer 130 respectively, then the tunnel insulation layer 120 can have a high polarization P2 that increases nonlinearly. The polarization P2 can increase the tunneling efficiency of the holes from the semiconductor substrate 101 toward the charge trap layer 130 by acting as an attractive force on the holes in the semiconductor substrate 101.

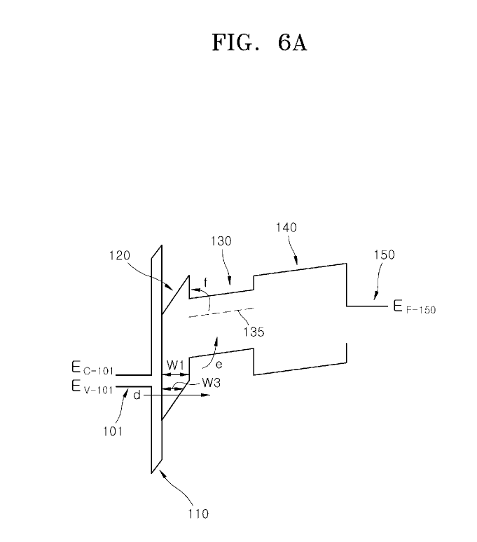

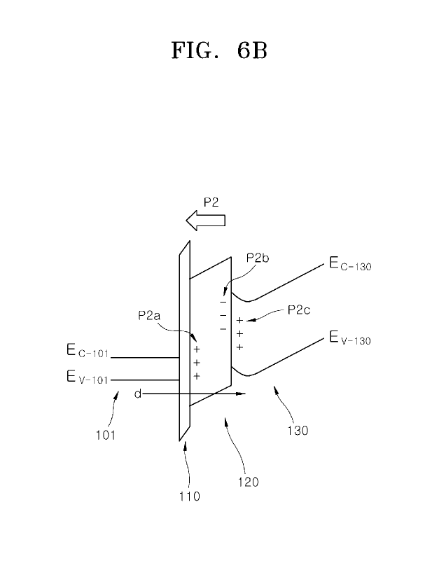

In addition, the polarization P2 of the tunnel insulation layer 120 can, for example, help to reduce a tunneling barrier width of the holes during the erase operation, as illustrated in energy band diagrams of FIGS. 6A and 6B described later. That is, the polarization state of the tunnel insulation layer 120 can increase the tunneling efficiency of the holes. The holes flowing into the charge trap layer 130 recombine with electrons in trap sites so that electrons can be removed, eliminated, or erased from the charge trap layer 130.

As a result, the reliability of an erase operation of a nonvolatile memory device can be improved by utilizing the antiferroelectricity of the tunnel insulation layer 120. Further, the magnitude of the voltage required for an erase operation can be reduced by utilizing the antiferroelectricity of the tunnel insulation layer 120. Thus, the power consumption of the nonvolatile memory device can be reduced.

FIG. 5A is an energy diagram schematically illustrating a programming operation of a nonvolatile memory device according to an embodiment of the present disclosure. FIG. 5B is an enlarged view schematically illustrating an interface between a tunnel insulation layer and a charge trap layer of the nonvolatile memory device of FIG. 5A. A configuration of the nonvolatile memory device may be substantially the same as the configuration of the nonvolatile memory device described above and with reference to FIGS. 1 and 2. That is, the tunnel insulation layer 120 of the nonvolatile memory device may include an antiferroelectric material.

FIG. 5A illustrates an embodiment where a metal layer having a predetermined Fermi energy level E_{F-150} is used as a control gate electrode 150. However, the present disclosure is not limited thereto, and in other embodiments, an n-type doped silicon layer may be used as the control gate electrode 150. In such embodiments, the Fermi energy level E_{F-150} can be replaced with a conduction band energy level E_{c} of the n-type doped silicon layer in the energy band diagram of FIG. 5A, but the shape of the overall energy band diagram does not substantially change.

Referring to FIGS. 5A and 5B, in an embodiment, a programming voltage may be applied to the nonvolatile memory device. Specifically, a positive bias may be applied to the control gate electrode 150 and a relatively negative bias may be applied to a substrate 101. The energy bands of the substrate 101, tunnel insulation layer 120, charge trap layer 130, charge blocking layer 140 and control gate electrode 150 may each be bent, respectively, as illustrated in FIGS. 5A and 5B, by the programming voltage.

Referring again to FIGS. 5A and 5B, in an embodiment, the programming operation may be achieved by sequentially performing an FN tunneling operation (a) in which electrons located above the conduction band E_{c-101} in the semiconductor substrate 101 pass through the tunnel insulation layer 120, and a trapping operation (b) in which the tunneled electrons reach the trap sites 135 in the charge trap layer 130. The FN tunneling operation (a) may be performed with an electron tunneling width of the tunnel insulation layer 120 reduced from a first width W1 to a second width W2 by application of a programming voltage and formation of an internal polarization in the tunnel insulation layer 120, as illustrated in FIGS. 3, 5A and 5B. As the electron tunneling width is reduced, the tunneling efficiency can be effectively increased. The electrons reaching the trap sites 135 are clogged by an energy barrier formed at an interface with charge blocking layer 140 so that a conduction operation (c) to the control gate electrode 150 can be suppressed.

Referring to FIG. 5B, in an embodiment, charge trap layer 130 can be charged with negative charges, in an interface region P1c with the tunnel insulation layer 120, by electrons moved into the charge trap layer 130 by tunneling. Accordingly, one region P1b of the tunnel insulation layer 120, which interfaces with the charge trap layer 130, can be charged with positive charges, and another region P1a of the tunnel insulation layer 120, which interfaces with the interfacial insulation layer 110, can be charged with negative charges. In other words, polarization P1 can be formed inside the tunnel insulation layer 120. The bending inclination of the energy band diagram of the tunnel insulation layer 120 can be increased by the polarization P1, and the tunneling width of the electrons can be more effectively reduced. In other words, the polarization P1 can help the tunneling width of the electrons of the tunnel insulation layer 120 decrease from a first width W1 to a second width W2.

FIG. 6A is an energy diagram schematically illustrating an erase operation of a nonvolatile memory device according to an embodiment of the present disclosure. FIG. 6B is an enlarged view schematically illustrating an interface between a tunnel insulation layer and a charge trap layer of the nonvolatile memory device of FIG. 6A. A configuration of the nonvolatile memory device may be substantially the same as the configuration of the nonvolatile memory device described above and with reference to FIGS. 1 and 2. That is, the tunnel insulation layer 120 of the nonvolatile memory device may include an antiferroelectric material.

Referring to FIGS. 6A and 6B, in an embodiment, an erase voltage may be applied to the nonvolatile memory device. Specifically, a negative bias may be applied to a control gate electrode 150 and a relatively positive bias may be applied to a semiconductor substrate 101. The energy bands of the substrate 101, tunnel insulation layer 120, charge trap layer 130, charge blocking layer 140 and control gate electrode 150 can each be bent, respectively, as illustrated in FIGS. 6A and 6B, by the erase voltage. The erase operation may be achieved by sequentially performing a tunneling operation (d) in which holes located below a valence band energy level Eᵥ₋₁₀₁ in the semiconductor substrate 101 pass through the tunnel insulation layer 120, and a tunneling operation (e) in which the tunneled holes recombine with electrons in trap sites 135 in the charge trap layer 130. The hole tunneling operation (d) may be performed with a hole tunneling width of the tunnel insulation layer 120 reduced from a first width W1 to a second width W3 by application of an erase voltage and formation of an internal polarization in tunnel insulation layer 120, as illustrated in FIGS. 4, 6A and 6B. As the hole tunneling width is reduced, the tunneling efficiency can be effectively increased. When an erase voltage is applied, electrons located in the trap sites 135 are clogged by an energy barrier formed at an interface with tunnel insulation layer 120 so that deviation (f) to the outside of the charge trap layer 130 can be suppressed. Therefore, recombination of the electrons and tunneled holes may be effectively performed in the charge trap layer 130.

Referring to FIG. 6B, in an embodiment, the charge trap layer 130 can be charged with positive charges, at an interface region P2c with the tunnel insulation layer 120, by holes moved into the charge trap layer 130 by tunneling. Accordingly, one region P2b of the tunnel insulation layer 120, which interfaces with the charge trap layer 130, can be charged with negative charges, and another region P2a, which interfaces with the interfacial insulation layer 110, can be charged with positive charges. In other words, polarization P2 can be formed inside the tunnel insulation layer 120. The bending inclination of the energy band diagram of the tunnel insulation layer 120 can be increased by the polarization P2, and the tunneling width of the holes can be more effectively reduced. In other words, the polarization P2 can help the tunneling width of the holes of the tunnel insulation layer 120 decrease from a first width W1 to a second width W3.

As described above, according to an embodiment of the present disclosure, a nonvolatile memory device may include a tunnel insulation layer, a charge trap layer, and a control gate electrode that are stacked sequentially on a semiconductor substrate. The tunnel insulation layer may include an antiferroelectric material.

When an electric field of an absolute magnitude greater than or equal to an absolute magnitude of a threshold electric field is formed in the tunnel insulation layer, the tunnel insulation layer has a nonlinearly increasing polarization value and the tunneling efficiency of electrons or holes generated between the semiconductor substrate and the charge trap layer can be increased. Accordingly, the charge filling efficiency or charge removing efficiency, respectively, of a charge trap layer can be increased.

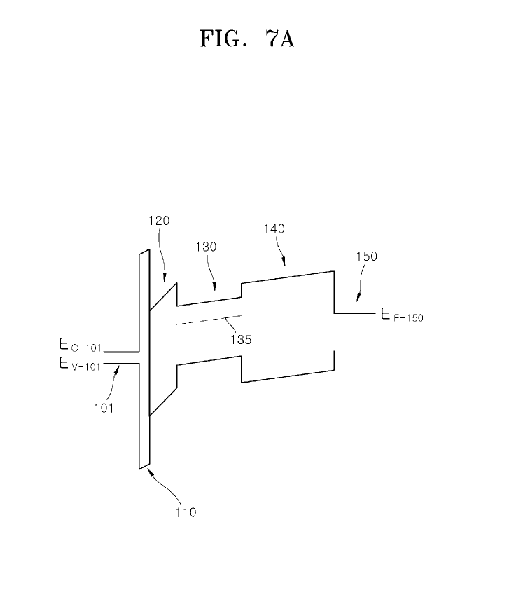

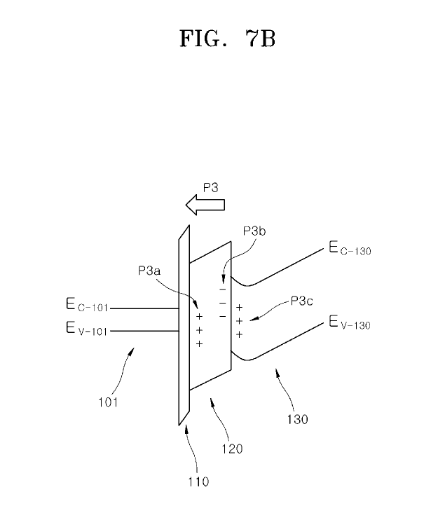

FIG. 7A is an energy diagram schematically illustrating a state in which a programming operation of a nonvolatile memory device according to an embodiment of the present disclosure is completed. FIG. 7B is an enlarged view schematically illustrating an interface between a tunnel insulation layer and a charge trap layer of the nonvolatile memory device of FIG. 7A. A configuration of the nonvolatile memory device may be substantially the same as the configuration of the nonvolatile memory device described above and with reference to FIGS. 1 and 2. In an embodiment, the band gap energy of the charge trap layer 130 may be less than the band gap energy of a tunnel insulation layer 120 and a charge blocking layer 140.

Referring to FIGS. 7A and 7B, in an embodiment, the programming voltage applied to a control gate electrode 150 may be removed after the programming operation in a nonvolatile memory device is completed. Accordingly, a single level or a multilevel electric signal can be stored in the charge trap layer, based on the amount of the charges charged or stored by the programming operation.

Referring to FIG. 7B, in an embodiment, the band gap energy of the charge trap layer 130 may be less than the band gap energy of the tunnel insulation layer 120. After the programming voltage is removed, an electron depletion region P3c, which interfaces with tunnel insulating layer 120, may be charged with positive charges and may be formed in an inner region of the charge trap layer 130. A region P3b of the tunnel insulating layer 120, which interfaces with the charge trap layer 130, can be charged with negative charges and another region P3a of the tunnel insulating layer 120, which interfaces with the interfacial insulation layer 110, can be charged with positive charges. In other words, a polarization P3 can be formed inside the tunnel insulation layer 120. The polarization P3 may be weaker than the polarization P2 of the tunnel insulation layer 120 in the erase operation described above and with reference to FIGS. 6A and 6B. However, a polarization P3 represents electrostatic attractive force and repulsive force in a direction illustrated in FIG. 7B, so that the electrons can be prevented, suppressed, or impeded from flowing into the tunnel insulation layer 120 from the charge trap layer 130. In addition, polarization P3 can also increase the bending gradient of the energy band diagram of the tunnel insulation layer 120 to increase the energy barrier for electrons between semiconductor substrate 101 and charge trap layer 130.

As a result, according to an embodiment of the present disclosure, since a nonvolatile memory device has a tunnel insulation layer including an antiferroelectric material, charges stored in a charge trap layer can effectively be prevented, suppressed, or impeded from flowing toward the semiconductor substrate after the programming operation.

The embodiments of the inventive concept have been disclosed above for illustrative purposes. Those of ordinary skill in the art will appreciate that various modifications, additions and substitutions are possible, without departing from the scope and spirit of the inventive concept as disclosed in the accompanying claims.

What is claimed is:

1. A nonvolatile memory device comprising:
a semiconductor substrate;
a tunnel insulation layer disposed on the semiconductor substrate;
a charge trap layer disposed on the tunnel insulation layer; and
a control gate electrode disposed on the charge trap layer,
wherein the tunnel insulation layer comprises an antiferroelectric material.

2. The nonvolatile memory device of claim 1, wherein the antiferroelectric material comprises one of zirconium oxide, hafnium oxide, and zirconium hafnium oxide.

3. The nonvolatile memory device of claim 2, wherein the antiferroelectric material comprises aluminum (Al) or silicon (Si) as a dopant.

4. The nonvolatile memory device of claim 1, wherein the tunnel insulation layer comprises a zirconium oxide layer having a thickness of 1 nm to 35 nm.

5. The nonvolatile memory device of claim 1, wherein the tunnel insulation layer has a thickness of 1 nm to 20 nm, and comprises a hafnium oxide layer doped with aluminum (Al) or silicon (Si).

6. The nonvolatile memory device of claim 1, further comprising
an interfacial insulation layer disposed between the semiconductor substrate and the tunnel insulation layer.

7. The nonvolatile memory device of claim 6, wherein the interfacial insulation layer comprises one selected from silicon oxide, silicon oxynitride, and silicon nitride.

8. The nonvolatile memory device of claim 1, further comprising
a charge blocking layer disposed between the charge trap layer and the control gate electrode.

9. A nonvolatile memory device comprising:
a semiconductor substrate;
a tunnel insulation layer disposed on the semiconductor substrate;
a charge trap layer disposed on the tunnel insulation layer; and
a control gate electrode disposed on the charge trap layer,
wherein the tunnel insulation layer has a nonlinearly increasing polarization value which improves tunneling of charges between the semiconductor substrate and the charge trap layer, when an electric field of an absolute magnitude greater than or equal to an absolute magnitude of a threshold electric field is formed in the tunnel insulation layer.

10. The nonvolatile memory device of claim 9, wherein the tunnel insulation layer comprises one of zirconium oxide, hafnium oxide, and zirconium hafnium oxide.

11. The nonvolatile memory device of claim 10, wherein the tunnel insulation layer comprises aluminum (Al) or silicon (Si) as a dopant.

12. The nonvolatile memory device of claim 9, wherein the tunnel insulation layer comprises a zirconium oxide layer having a thickness of 1 nm to 35 nm.

13. The nonvolatile memory device of claim 9, wherein the tunnel insulation layer has a thickness of 1 nm to 20 nm, and comprises a hafnium oxide layer doped with aluminum (Al) or silicon (Si).

14. The nonvolatile memory device of claim 9, further comprising
an interfacial insulation layer disposed between the semiconductor substrate and the tunnel insulation layer.

15. The nonvolatile memory device of claim 14, wherein the interfacial insulation layer comprises one selected from silicon oxide, silicon oxynitride, and silicon nitride.

16. The nonvolatile memory device of claim 9, further comprising
a charge blocking layer disposed between the charge trap layer and the control gate electrode.

17. A nonvolatile memory device comprising:
a semiconductor substrate;
an interfacial insulation layer disposed on the semiconductor substrate;
an antiferroelectric tunnel insulation layer disposed on the interfacial insulation layer;
a charge trap nitride layer disposed on the tunnel insulation layer; and
a control gate electrode disposed on the charge trap nitride layer,
wherein the tunnel insulation layer comprises one of zirconium oxide, hafnium oxide, and zirconium hafnium oxide; and
wherein the interfacial insulation layer comprises one selected from silicon oxide, silicon oxynitride, and silicon nitride.

18. The nonvolatile memory device of claim 17, wherein the tunnel insulation layer has a nonlinearly increasing polarization value which improves tunneling of charges between the semiconductor substrate and the charge trap nitride layer, when an electric field of an absolute magnitude greater than or equal to an absolute magnitude of a threshold electric field is formed in the tunnel insulation layer.

19. The nonvolatile memory device of claim 17, wherein the tunnel insulation layer comprises a zirconium oxide layer having a thickness of 1 nm to 35 nm.

20. The nonvolatile memory device of claim 17, wherein the tunnel insulation layer has a thickness of 1 nm to 20 nm, and comprises a hafnium oxide layer doped with aluminum (Al) or silicon (Si).
